(19) United States
(12) Patent Application Publication
(10) Pub. No.: US 2024/0396301 A1
(43) Pub. Date: Nov. 28, 2024

(54) Dynamic control of laser transverse mode

(71) Applicant: APPLE INC., Cupertino, CA (US)

(72) Inventors: Pengfei Qiao, El Cerrito, CA (US); Chinhan Lin, Santa Clara, CA (US); Fei Tan, San Jose, CA (US); Alexander Hein, Munich (DE)

(21) Appl. No.: 18/321,016

(22) Filed: May 22, 2023

(51) Int. Cl. H01S 5/183; H01S 5/00; H01S 5/02; H01S 5/062; H01S 5/30

(52) U.S. Cl. CPC H01S 5/18302; H01S 5/0085; H01S 5/021; H01S 5/0622; H01S 5/06236; H01S 5/3013

(57) ABSTRACT

An optoelectronic apparatus includes a semiconductor substrate, an electrically activated spatial light modulator disposed on the semiconductor substrate, and a vertical-cavity surface-emitting laser (VCSEL) disposed over the spatial light modulator on the semiconductor substrate. A controller is coupled to actuate the VCSEL to emit a beam of optical radiation and to control the spatial light modulator so as to modify an optical property of the beam.

### FIELD OF THE INVENTION

The present invention relates generally to optoelectronic devices, and particularly to emitters of optical radiation.

### BACKGROUND

Vertical-cavity surface-emitting lasers (VCSELs) are widely used as sources of optical radiation both as single sources and as arrays of emitters. Their attributes include high optical power, narrow linewidth, and high efficiency, and they are advantageously used in applications such as optical communications and LiDAR (light detection and ranging).

### SUMMARY

Embodiments of the present invention that are described hereinbelow provide improved methods and designs for controlling the emission of VCSELs.

There is therefore provided, in accordance with an embodiment of the invention, an optoelectronic apparatus, including a semiconductor substrate, an electrically activated spatial light modulator disposed on the semiconductor substrate, and a vertical-cavity surface-emitting laser (VCSEL) disposed over the spatial light modulator on the semiconductor substrate. A controller is coupled to actuate the VCSEL to emit a beam of optical radiation and to control the spatial light modulator so as to modify an optical property of the beam.

In a disclosed embodiment, the controller is configured to drive the spatial light modulator so as to select a transverse mode of the beam. Additionally or alternatively, the controller is configured to drive the spatial light modulator so as to switch the transverse mode of the beam among a plurality of different transverse modes.

In one embodiment, the controller is configured to drive the spatial light modulator to modify a polarization of the VCSEL.

In another embodiment, the controller is configured to drive the spatial light modulator to tune a wavelength of the VCSEL.

In a disclosed embodiment, the spatial light modulator includes a liquid crystal. Additionally or alternatively, the semiconductor substrate includes silicon, and the spatial light modulator includes a liquid crystal on silicon (LCoS) component. Further additionally or alternatively, the VCSEL includes an epitaxial stack on a die made of a III-V semiconductor material, which is mounted on the silicon substrate over the LCoS component. Additionally or alternatively, the die is mounted on the silicon substrate in a back-side emitting configuration.

In a further embodiment, the controller includes logic circuits disposed on the silicon substrate.

In a disclosed embodiment, the spatial light modulator includes a micro-electromechanical systems (MEMS) array.

In a further embodiment, the spatial light modulator includes a thermoelectrically tunable phase-change material.

In another embodiment, the spatial light modulator includes an array of pixels, and the controller is configured to drive the spatial light modulator to vary respective amplitudes of reflection coefficients of the pixels.

In yet another embodiment, the spatial light modulator includes an array of pixels, and the controller is configured to drive the spatial light modulator to vary respective phases of reflection coefficients of the pixels.

In a disclosed embodiment, the spatial light modulator is configured to function as a diffractive optical element.

In a further embodiment, the spatial light modulator is configured to function as a metasurface.

There is also provided, in accordance with an embodiment of the invention, a method for beam generation. The method includes providing a semiconductor substrate with an electrically activated spatial light modulator disposed on the semiconductor substrate, mounting a vertical-cavity surface-emitting laser (VCSEL) over the spatial light modulator on the semiconductor substrate, and actuating the VCSEL to emit a beam of optical radiation while controlling the spatial light modulator so as to modify an optical property of the beam.

The present invention will be more fully understood from the following detailed description of the embodiments thereof, taken together with the drawings in which:

### BRIEF DESCRIPTION OF THE DRAWINGS

FIG. 1 is a schematic side view of an optoelectronic apparatus, in accordance with an embodiment of the invention;

FIGS. 2A, 2B, 2C, and 2D are schematic cross-sectional views of the modulation patterns of the SLM of the apparatus of FIG. 1, in accordance with embodiments of the invention; and

FIGS. 3A, 3B, 3C, and 3D are schematic cross-sectional views of transverse modes of the beam emitted by the apparatus of FIG. 1 in response to the modulation patterns of the SLM shown in FIGS. 2A-2D, in accordance with embodiments of the invention.

### DETAILED DESCRIPTION OF EMBODIMENTS

### Overview

In a conventional VCSEL, the beam characteristics are determined by the design of the device and the semiconductor fabrication process by which the VCSEL is produced. Once the device has been fabricated, system integrators and users have little or no control over parameters of the emitted beam, such as transverse modes, divergence, wavelength, and polarization.

Embodiments of the present invention address these shortcomings by providing integrated optoelectronic devices that enable real-time control of the VCSEL beam parameters, particularly (but not only) the transverse modes of the emitted beam. In these embodiments, a VCSEL is mounted on a semiconductor substrate, such as a silicon substrate. An electrically controlled spatial light modulator (SLM), such as an LCoS (Liquid Crystal on Silicon) component, is disposed on the substrate directly under the VCSEL and is optically integrated with the optical cavity of the VCSEL. By controlling the pattern formed by the elements of the SLM while actuating the VCSEL, different transverse modes of the VCSEL output beam can be selected. Additionally or alternatively, the SLM pattern can be modulated to control other beam properties, such as rotating the polarization and/or to tuning the wavelength of the VCSEL.

The disclosed embodiments provide an optoelectronic apparatus, comprising a semiconductor substrate, an electrically activated spatial light modulator disposed on the semiconductor substrate, and a vertical-cavity surface-emitting laser (VCSEL) disposed over the spatial light modulator on the semiconductor substrate. A controller actuates the VCSEL to emit a beam of optical radiation and controls the spatial light modulator so as to select a transverse mode of the beam.

### Optoelectronic Apparatus

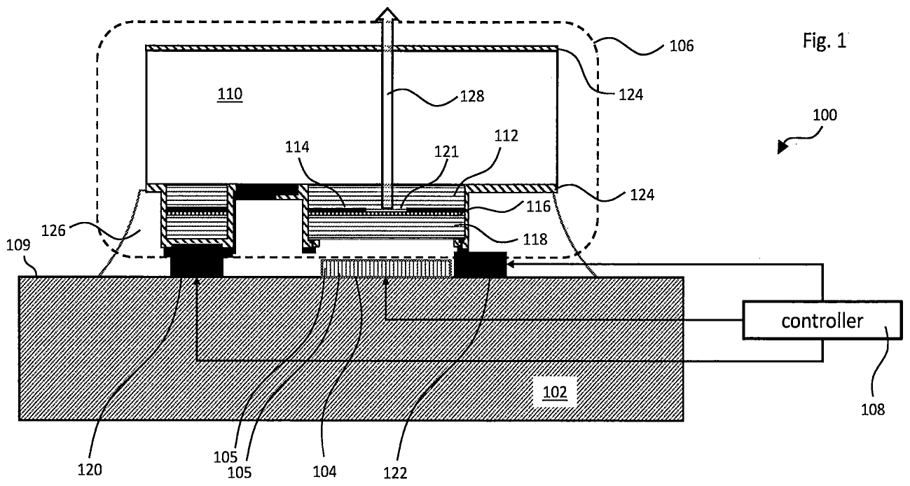

FIG. 1 is a schematic side view of an optoelectronic apparatus 100, in accordance with an embodiment of the invention. Apparatus 100 comprises a silicon substrate 102, a spatial light modulator (SLM) 104 formed or otherwise mounted on the semiconductor substrate, and a vertical-cavity surface-emitting laser (VCSEL) 106 mounted over the SLM on the semiconductor substrate. Additionally or alternatively, VCSEL 106 may comprise an integrated spatial light modulator, for example in the form of an active metasurface. A controller 108, comprising electronic logic and drive circuits, is coupled to control SLM 104 and VCSEL 106. Although controller 108 is shown in FIG. 1, for the sake of clarity, as a separate block, it may conveniently be implemented on silicon substrate 102, for example in the form of CMOS circuits.

In the present embodiment, SLM 104 comprises an LCoS component with multiple pixels 105 arranged in a two-dimensional matrix over a top surface 109 of substrate 102. SLM 104 may comprise any suitable type of electrooptic material, such as a nematic liquid crystal or a cholesteric liquid crystal, possibly with a polymer additive. Each pixel 105 is controlled by controller 108 via a corresponding microelectrode (not shown). By changing the voltage on the corresponding microelectrode, controller 108 is able to modulate both the amplitude and the phase of the reflection coefficient (the ratio of the reflected to incident electric field) of each pixel between the values of 0 and 1 and of 0 and 2π, respectively. By appropriate choice of the driving voltages, controller is able to drive SLM 104 to function as a mirror of variable size and shape or as a metasurface or other type of diffractive optical element.

In alternative embodiments, SLM 104 may comprise other sorts of optical modulators. For example, in one embodiment, SLM 104 comprises a micro-electromechanical systems (MEMS) device, such as an array of controllable micromirrors. In another embodiment, SLM 104 comprises a thermoelectrically tunable phase-change material, such as vanadium dioxide (VO₂), driven by controller 108.

VCSEL 106 comprises a III-V semiconductor die 110, such as a gallium-arsenide (GaAs) die, on which a stack of epitaxial layers has been deposited and patterned. These layers define an upper distributed Bragg reflector (DBR) 112, an oxide confinement layer 114, an active region 116, and a lower DBR 118. (The terms “upper” and “lower” reflect the respective locations of DBRs 112 and 118 in apparatus 100, in which die 110 has been flipped upside down after fabrication of VCSEL 106. During fabrication, DBR 112 is deposited first on a III-V semiconductor substrate and is then overlaid by the other layers.) Active region 116 comprises one or more quantum wells, and oxide layer 114 is etched to define an aperture 121 of VCSEL 106. VCSEL 106 is isolated from its surroundings by a passivation layer 124.

DBRs 112 and 118 together form the laser cavity of VCSEL 106. After fabrication of VCSELs 106 on the III-V substrate, the substrate is thinned and diced, and the VCSEL die is mounted on substrate 102 over SLM 104 in a “back-side emission” configuration. In this configuration, VCSEL 106 emits optical radiation as a beam 128 passing upward through DBR 112 and die 110. (Alternatively, VCSEL may be configured, mutatis mutandis, for front-side emission through DBR 118, with GaAs substrate adjoining SLM 104.) Anode and cathode electrodes 120 and 122 couple the driving current from controller 108 to active region 116 for generating emission of optical radiation. The active components of VCSEL 106 and its connections to silicon substrate 102 are encapsulated in an adhesive 126.

Lower DBR 118 is partially transmitting so that SLM 104 contributes to the overall reflectance of the lower DBR and thus is able to influence the transverse mode structure of VCSEL 106. Additionally or alternatively, the phase pattern applied by SLM 104 may be adjusted to control the polarization and/or to tune the wavelength of the VCSEL.

In addition to the logic and drive circuits mentioned above, controller 108 may also comprise a programmable processor, which is programmed in software and/or firmware to control SLM 104, as well as actuating VCSEL 106. Although controller 108 is shown in the figures, for the sake of simplicity, as a single, monolithic functional block, in practice the controller may comprise multiple circuits and interfaces, as will be apparent to those skilled in the art.

### Control of Transverse Modes

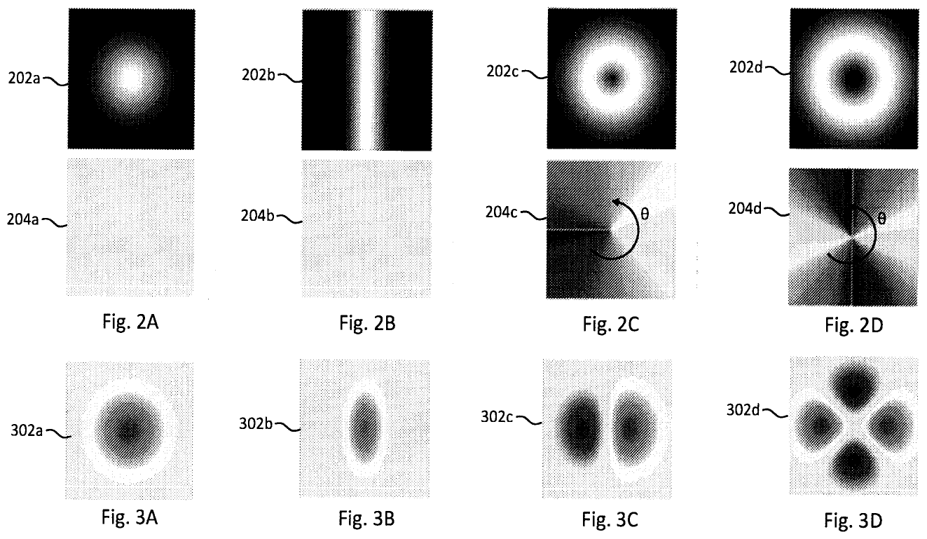

FIGS. 2A, 2B, 2C, and 2D are schematic cross-sectional views of modulation patterns of SLM 104 in apparatus 100 (FIG. 1), in accordance with embodiments of the invention.

Each of FIGS. 2A-2D shows a cross-sectional view of the spatial distribution of the amplitude and phase of the respective reflection coefficient of SLM 104. Thus, a view 202a in FIG. 2A indicates the amplitude of the reflection coefficient, with white indicating a high value, black a low value, and shades of gray an intermediate value. Similarly in FIG. 2A, a view 204a indicates the phase of the reflection coefficient, which in this case in constant (meaning that SLM 104 modulates only the amplitude of the VCSEL beam). Similarly, FIGS. 2B-2D show respective reflection coefficient amplitudes and phases in views 202b/204b, 202c/204c, and 202d/204d. The gray scale in views 204c and 204d represents the phase variation in over the area of the SLM over a range from −2π to +2π.

Views 204a and 204b show a constant phase across SLM 104. View 204c shows a phase that changes linearly from −2π to +2π with a rotation angle θ around the center of SLM 104. View 204d shows a phase that changes linearly twice from −2π to +2π with a rotation angle θ, i.e., with two full rotations around the center of SLM 104. The behavior of the phase in views 204c and 204d is termed a vortex-like behavior.

In additional embodiments, other spatial distributions of the amplitude and phase of the reflection coefficient of SLM 104 may be implemented.

FIGS. 3A, 3B, 3C, and 3D are schematic cross-sectional views of transverse modes of beam 128 emitted by apparatus 100 in response to the modulation patterns of SLM 104 of FIGS. 2A-2D.

The amplitudes of the transverse modes of beam 128 are indicated in FIGS. 3A-3D in respective views 302a-302d in a reverse grayscale, i.e., dark grey indicates a high amplitude, whereas light gray indicates a low amplitude.

View 302a in FIG. 3A shows a circularly symmetrical transverse mode due to the circularly symmetrical amplitude and constant phase of the reflection coefficient of SLM 104, shown in views 202a and 204a (FIG. 2A). View 302b in FIG. 3B shows an elongated transverse mode due to a slit-like amplitude and constant phase of the reflection coefficient of SLM 104, shown in views 202b and 204b (FIG. 2B). View 302c in FIG. 3C shows a two-lobed transverse mode due to a combination of an annular amplitude and a vortex-like phase of the reflection coefficient of SLM 104, shown in views 202c and 204c (FIG. 2C). View 302d in FIG. 3D shows a four-lobed transverse mode due to a combination of an annular amplitude and a twice-rotated vortex-like phase of the reflection coefficient of SLM 104, shown in views 202d and 204d (FIG. 2D).

These particular modulation patterns and the corresponding beam modes are shown by way of example. The addressable amplitude and phase modulation of SLM 104 make it possible to generate a wide variety of other beam patterns, depending on application requirements.

In alternative embodiments, the polarization state or a combination of the intensity and the polarization state of the transverse mode of beam 128 may be selected by a suitable selection of amplitude/phase modulation pattern of pixels 105 of SLM 104. Additionally or alternatively, the phases of pixels 105 may be modulated in order to tune the emission wavelength of VCSEL 106 over a certain range.

It will be appreciated that the embodiments described above are cited by way of example, and that the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optoelectronic apparatus, comprising:
a semiconductor substrate;
an electrically activated spatial light modulator disposed on the semiconductor substrate;
a vertical-cavity surface-emitting laser (VCSEL) disposed over the spatial light modulator on the semiconductor substrate; and
a controller coupled to actuate the VCSEL to emit a beam of optical radiation and to control the spatial light modulator so as to modify an optical property of the beam.

2. The apparatus according to claim 1, wherein the controller is configured to drive the spatial light modulator so as to select a transverse mode of the beam.

3. The apparatus according to claim 2, wherein the controller is configured to drive the spatial light modulator so as to switch the transverse mode of the beam among a plurality of different transverse modes.

4. The apparatus according to claim 1, wherein the controller is configured to drive the spatial light modulator to modify a polarization of the VCSEL.

5. The apparatus according to claim 1, wherein the controller is configured to drive the spatial light modulator to tune a wavelength of the VCSEL.

6. The apparatus according to claim 1, wherein the spatial light modulator comprises a liquid crystal.

7. The apparatus according to claim 6, wherein the semiconductor substrate comprises silicon, and the spatial light modulator comprises a liquid crystal on silicon (LCoS) component.

8. The apparatus according to claim 7, wherein VCSEL comprises an epitaxial stack on a die made of a III-V semiconductor material, which is mounted on the silicon substrate over the LCoS component.

9. The apparatus according to claim 8, wherein the die is mounted on the silicon substrate in a back-side emitting configuration.

10. The apparatus according to claim 8, wherein the controller comprises logic circuits disposed on the silicon substrate.

11. The apparatus according to claim 1, wherein the spatial light modulator comprises a micro-electromechanical systems (MEMS) array.

12. The apparatus according to claim 1, wherein the spatial light modulator comprises a thermoelectrically tunable phase-change material.

13. The apparatus according to claim 1, wherein the spatial light modulator comprises an array of pixels, and wherein the controller is configured to drive the spatial light modulator to vary respective amplitudes of reflection coefficients of the pixels.

14. The apparatus according to claim 1, wherein the spatial light modulator comprises an array of pixels, and wherein the controller is configured to drive the spatial light modulator to vary respective phases of reflection coefficients of the pixels.

15. The apparatus according to claim 1, wherein the spatial light modulator is configured to function as a diffractive optical element.

16. The apparatus according to claim 11, wherein the spatial light modulator is configured to function as a metasurface.

17. A method for beam generation, comprising:
providing a semiconductor substrate with an electrically activated spatial light modulator disposed on the semiconductor substrate;
mounting a vertical-cavity surface-emitting laser (VCSEL) over the spatial light modulator on the semiconductor substrate; and
actuating the VCSEL to emit a beam of optical radiation while controlling the spatial light modulator so as to modify an optical property of the beam.

18. The method according to claim 17, wherein controlling the spatial light modulator comprises driving the spatial light modulator so as to select a transverse mode of the beam.

19. The method according to claim 17, wherein controlling the spatial light modulator comprises driving the spatial light modulator so as to switch the transverse mode of the beam among a plurality of different transverse modes.

20. The method according to claim 17, wherein controlling the spatial light modulator comprises driving the spatial light modulator to tune a wavelength of the VCSEL.
